(19) United States
(12) Patent Application Publication
(10) Pub. No.: US 2009/0202817 A1
(43) Pub. Date: Aug. 13, 2009

(54) METHOD FOR DEPOSITING A HYDROPHOBIC/OLELPYHOBIC LINING USING ATMOSPHERIC PLASMA WITH IMPROVED DURABILITY

(75) Inventors: Anne Durandeau, Paris (FR); Arnaud Huignard, Paris (FR); Herve Montigaud, Neuilly Sur Marne (FR); Fabrice Abbott, Paris (FR)

Correspondence Address: OBLON, SPIVAK, MCCLELLAND MAIER & NEUSTADT, P.C., 1940 DUKE STREET, ALEXANDRIA, VA, 22314, US

(73) Assignee: Saint-Gobain Glass France, Courbevoie (FR)

(21) Appl. No.: 12/304,222

(22) PCT Filed: Jun. 12, 2007
(86) PCT No.: PCT/FR2007/051421

§ 371 Date: Dec. 10, 2008

(30) Foreign Application Priority Data
Jun. 16, 2006 (FR) 0652159

(51) Int. Cl. B32B 17/00; B05D 3/00; C23C 14/34

(52) U.S. Cl. 428/332; 427/535; 204/192.15

(57) ABSTRACT

The invention relates to a method for synthesizing a hydrophobic/oleophobic coating on a glass, ceramic or glass-ceramic substrate, preferably glass substrate, by bringing said substrate into contact with a mixture of an excited gas originating from a device generating an atmospheric pressure plasma and of a gas containing at least one fluoro compound, said method being characterized in that a sublayer, the thickness of which is between 1 and 100 nm, is first deposited on said substrate.

It also relates to a product, comprising monolithic, laminated or multiple glazing, equipped on at least one part of at least one of its surfaces with a hydrophobic/oleophobic coating obtained by the implementation of the method.

The present invention relates to the treatment of a substrate to render the surface hydrophobic/oleophobic. The substrate according to the invention is especially composed of a glass material, a ceramic, or else a glass-ceramic.

The glazing units according to the invention are, for example, glass glazing units. They are used, in particular, in the aeronautical, railroad or automotive field. They may also be used in the construction field or in the field of interior fittings such as, for example, decorative panels, for furniture, domestic electrical appliances (refrigerator doors, oven doors, windows), etc.

This type of treatment aims, in a known manner, to give the substrate a “hydrophobic” character, for example to provide a rain-repellent functionality, and/or an oleophobic character, for example to provide an “easy-to-clean” or anti-graffiti functionality.

The term “wettability” denotes the property according to which polar or nonpolar liquids adhere to the substrate and form a troublesome film and also the tendency of a substrate to retain dust or dirt of any nature, finger marks, insects, etc.

The presence of water and/or of dirt is troublesome in particular for a transparent substrate of the glazing type used in particular in the field of transportation.

The property of nonwettability of a substrate, more commonly denoted hydrophobicity/oleophobicity, becomes more pronounced as the contact angles between a hydrophilic or oleophilic liquid and this substrate increase, for example at least 90° for water. The liquid then has a tendency to easily flow over the substrate in the form of drops by simple gravity, if the substrate is inclined, or under the effect of aerodynamic forces, in the case of a moving vehicle. Known agents for conferring this property of hydrophobicity/oleophobicity are, for example, fluoro alkylsilanes, such as disclosed in Patent Applications EP 0 492 417, EP 0 492 545 and EP 0 672 779. According to these documents, this layer can be obtained by applying, to the surface of a substrate, a solution comprising fluoro organosilanes in a nonaqueous organic solvent. The document EP 0 492 545 mentions, as nonaqueous organic solvent, in particular n-hexadecane, toluene, xylene, etc. These solvents are particularly appropriate for a fluoro chlorosilane. It is also possible, according to this document, to use a methyl or ethyl alcohol as solvent when the fluoro silane is a fluoro alkoxysilane.

Common hydrophobic/oleophobic agents are in particular alkylsilanes, the alkyl group of which comprises at least one perfluorinated end, that is to say consisting of an F₃C—(CF₂)ₙ— group, in which n is a positive integer or zero. Patent Application EP 0 719 743 indicates perfluorinated hydrocarbons as appropriate solvents for these. Other hydrophobic/oleophobic agents are also known, such as those described in Application US 2004/247886.

One of the most acute problems posed in the field of the invention is first of all that of the frictional resistance of the hydrophobic/oleophobic coating. This friction occurs more or less during operations in which the substrate is cleaned, which operations are periodically essential, in particular for restoring satisfactory vision through a transparent substrate. There is thus a constant search to slow down the gradual removal of the hydrophobic/oleophobic coatings of abovementioned types, which occurs in particular under the action of windshield wipers in the case of an automobile windshield or under the action of a blades in the case of sliding side windows. Moreover, such a removal can also result from decomposition by ultraviolet radiation.

It is known, from the abovementioned Application EP 0 492 545 A2, to increase the frictional resistance of a hydrophobic/oleophobic coating by depositing it via a liquid (sol-gel) route in a nonaqueous solvent and by subjecting the substrate to a priming treatment before applying the coating. This treatment consists in forming a thin intermediate layer from “priming agents” or “primers” which are silicon compounds having at least two hydrolyzable functional groups. In a well known way, one of the two hydrolyzable functional groups makes possible the chemical bonding to the substrate by an oxygen atom bonded to the silicon atom; the second hydrolyzable functional group making possible the attachment of the hydrophobic/oleophobic agent. Application EP 0 492 545 A2 mentions, as priming agents, the compounds SiCl₄, SiHCl₃, SiH₂Cl₂ and Cl—(SiCl₂O)ₙSiCl₃, n being an integer between 1 and 4.

Patent EP 799 873 discloses more particularly rain-repellent coatings prepared by the liquid route and comprising a silica-based sublayer obtained from a precursor of the Si(OEt)₄ or SiCl₄ type and a perfluoroalkylsilane-based functional layer.

In order to further improve the mechanical strength properties of the hydrophobic coating, Patent EP 1 102 825 discloses a composition for a hydrophobic/oleophobic coating incorporating both a fluoro alkylsilane and a disilane, said composition being applied to a sublayer of the type described previously.

The deposition techniques used may be of various natures. The most common consists of applying the material forming the hydrophobic/oleophobic layer or the sublayer (or usually a precursor of these) using an impregnated cloth.

This technique is well known in the art under the term “wiping”. In general, the material or its precursor is brought to the surface of the substrate via a dilute water/alcohol solution additionally comprising a catalyst system that incorporates the mixture of an alcohol and an acid, as described in Application JP 5-311156. Other techniques for depositing via a liquid route are also known, which make it possible to obtain coatings of a substantially identical quality, in particular the spraying techniques (a process often referred to as “spray-coating”) as described in Application EP 545 201 A2, which furthermore allow a better control of the thickness of the layers, or else centrifuging techniques, according to processes known in the art by the term “spin-coating”, dipping techniques (processes usually known as “dip-coating”) or else sprinkling techniques (processes usually known as “flow-coating”).

While such sublayers make it possible to obtain performances that conform to the great majority of current mechanical strength specifications, such as, for example, those imposed by automobile manufacturers, especially frictional resistance, they do not generally exhibit a sufficient chemical inertia that typically allows them to satisfy criteria of salt corrosion resistance.

In particular, the tests carried out by the Applicant have demonstrated that, in the majority of cases, such coatings had difficulty satisfying the specifications imposed by automobile manufacturers with regard to the subject and measured, for example, by the test for resistance to Neutral Salt Spray (NSS) according to the NF ISO 9227 standard. Thus, the coatings described in Applications EP 799 873 and EP 1 102 825, the performances of which with regard to UV resistance and mechanical strength appear satisfactory, have inadequate performances with regard to salt corrosion, as measured by the NSS test. This inadequacy could limit their current and future development, in particular in the Asian market where the standards are the strictest in this field.

In order to obtain a coating comprising both good properties in terms of frictional resistance and in terms of chemical resistance, in particular resistance to salt corrosion, the Applicant has proposed according to a first route, in Applications WO 2005/118501 or WO 2005/084943, to deposit a sublayer in the form of a thin film of metal oxides on the support, then to subject this thin film to an operation of exciting the sublayer with a plasma, which may range up to etching, in order to make the surface thereof rough. The hydrophobic coating is then applied to the roughened surface. In this way, very good properties were obtained both with regard to the mechanical strength of the hydrophobic coating, and to its chemical resistance, within the meaning described previously. However, although such a coating is technically very high performance, the excessive cost and the complexity of such a process limits its application. Moreover, the surface roughness leads to a substantial increase in the hysteresis, calculated by the difference between the advancing and receding contact angles of the drop of water or of oil and consequently an increase in the detachment volume of said drop on a sloped support, which is expressed by a drop in the performance of the desired functionality.

Patent Application US 2004/247886 describes a method of synthesizing a hydrophobic thin film on a substrate, especially a glass substrate, by bringing said substrate into contact with the mixture of a discharge gas originating from a device generating an atmospheric pressure plasma and of a gas containing a fluorinated organometallic compound. The process described makes it possible to obtain, at a lower cost, thin films for which the mechanical properties are greater than those obtained by conventional liquid-route application techniques. This application does not however deal with the problem of the chemical resistance of the hydrophobic layers thus formed, in particular in the case where a glass substrate is used. In this case, the hydrolytic resistance of the material conditions its potential applications, especially outside.

The main subject of the present invention is thus coatings that are resistant not only to friction and to UV radiation but that also have a high chemical resistance, that is to say that typically enables them to meet the specifications imposed currently by the automotive industry, simultaneously in terms of frictional resistance, UV resistance and climatic durability. The coatings according to the invention also have performances essentially equal to those of the coatings known to date as regards the other specifications necessary for their various uses such as, for example, the initial water contact angle and the detachment volume of the drops.

More specifically, the present invention relates, according to a first aspect, to a method for synthesizing a hydrophobic coating on a glass, ceramic or glass-ceramic substrate, preferably glass substrate, by bringing said substrate into contact with a mixture of an excited gas originating from a device generating a substantially atmospheric pressure plasma and of a gas containing at least one fluoro organic compound, said method being characterized in that a sublayer, preferably an inorganic sublayer, the thickness of which is between 1 and 100 nm, is first deposited on said substrate. From an economic and technical point of view, the thinnest sublayers, that is to say those for which the thickness is typically between 5 and 50 nm, or even between 10 and 30 nm, are preferred according to the invention.

The fluoro compound precursor of the hydrophobic layer may be chosen from all the compounds currently known for this purpose.

For example, but without being limited thereto, the precursor may be chosen according to the invention from the following compounds: perfluorosilanes, polyether perfluorosilanes, mixtures that include a fluorocarbon and a precursor of silicon or of another metal chosen from the group Al, Ga, Sn, Ti, Ta, Cr, Z, Nb, In, Fe, Co, V, Y.

Surprisingly, in comparison with the hydrophobic coatings described up to now, the tests carried out by the Applicant have shown that such small thicknesses of the sublayer made it possible to obtain hydrophobic/oleophobic coatings for which the chemical durability was greatly improved, while retaining excellent initial performances, very good mechanical durability and acceptable UV resistance, characteristic of making them compatible with the strictest standards imposed by automobile manufacturers with regard to the subject, especially for applications to windshields. Most particularly, the tests carried out by the Applicant, the most significant of which have been reported in the following examples, show that a much more limited thickness of the sublayer, that is to say in the range of values described previously, leads to better results than those obtained according to the customary deposition techniques via a liquid or sol-gel route, as described, for example, in Patents EP 799 873 or EP 1 102 825.

In general, the sublayer is composed of at least one inorganic compound from the group made up of metal oxides, nitrides, carbides, or oxycarbides or oxynitrides.

For example, the sublayer is composed of an inorganic compound chosen from the group made up of Sio₂, Al₂O₃, Ga₂O₃, SnO₂, TiO₂, Ta₂O₅, Cr₂O₃, ZrO₂, Nb₂O₅, In₂O₃, Fe₂O₃, CoO₃, V₂O₅, Y₂O₃, TiN, SiOₓ with x less than 2, SiOₚC_{q} or SiOₚN_{q} with p between 1 and 2 and q.

According to one possible embodiment of the invention, the inorganic compound is optionally doped so as to make it electron and/or ion conducting or so as to improve the hydrolytic resistance thereof or else so as to modify the optical properties thereof.

According to the invention, the sublayer may be deposited by means of a device generating a substantially atmospheric pressure plasma.

Without departing from the scope of the invention, the sublayer may be deposited by magnetron sputtering, by thermal CVD or plasma-enhanced CVD at low pressure or by a sol-gel route.

Typically, the fluoro compound is a fluorinated organometallic compound of formula:

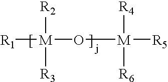

in which M is an element chosen from the group composed of Si, Ti, Al, Ge, Zr or Sn, R₁ to R₆ represent hydrogen or groups comprising at least one carbon atom, at least one of the groups R₁ to R₆ comprising fluorine.

For example, the fluoro compound is a fluorosilane of formula:

R-A-Z-[SiX₂O]ₙ—Si(X₃₋ₚ)(R′ₚ)

in which R is a fluorocarbon-based chain, A is a fluorocarbon-based chain that may be interrupted by ether —O— or thioether —S— groups, Z is a bridging group between the fluoro chain and the silane such as a carbon-based chain and X is a halogen, preferably Cl or I, or an alkoxy group and R′ is an alkyl group or a hydrogen atom, n being between 0 and 5 and p being between 0 and 3.

According to one possible embodiment, the fluoro compound is a perfluoroalkylsilane of formula:

F₃C—(CF₂)ₘ—(CH₂)ₙ—Si(X₃₋ₚ)(R′ₚ) (II)

in which:
m=0 to 15, preferably 5 to 9;
n=1 to 5, preferably n=2;
p=0, 1 or 2, preferably 0 or 1, very preferably 0;
R′ is an alkyl group or a hydrogen atom; and
X is a hydrolyzable group such as a halide group of the Cl type or an alkoxy group.

In an alternative embodiment of the invention, the fluoro compound is a fluorocarbon-based precursor comprising only C, H and F, of the saturated type corresponding to the formula CₙF₂ₙ₊₂ or of the unsaturated type corresponding to the formula CₙF₂, or of the fluoroether type corresponding to the formula CₙF₂ₙO, n being an integer that varies from 1 to 20.

Typically, the gas contains a mixture of at least one fluoro compound as described previously, in particular of the preceding fluorocarbon-based compound, and of at least one precursor, preferably chosen from the organometallics, organosilicas or halides of an element from the group composed of Si, Al, Ti, Sn or Zr.

Another subject of the invention consists of a product of which the outer surface, usually composed of a glass, ceramic or glass-ceramic material or a natural inorganic material, is at least partly equipped with a hydrophobic/oleophobic coating capable of being obtained by a method as described previously.

The product of the invention is, for example monolithic, laminated or multiple glazing.

It is pointed out that these terms are defined as follows:

“monolithic glazing”: glazing composed of a single sheet of glass;
“laminated glazing”: a stack of several sheets solidly attached to one another, for example sheets of glass or of plastic fixed to one another by means of polyvinyl-butyral, polyurethane, etc. adhesive layers; and
“multiple glazing”: an assembly of unattached sheets, that is to say, in particular, separated from one another by layers of air.

The advantage of the hydrophobic/oleophobic coating of the invention for this type of products is twofold. Firstly, it allows drops of water or another liquid to flow over vertical or inclined surfaces, optionally under the effect of aerodynamic forces, for example in the case of a moving vehicle. Furthermore, these drops that flow take in dirt and carry it away. The visibility through the glazing is improved to an extent such that it is possible to dispense, in some cases, with cleaning devices (window washers, windshield wipers).

Finally, another subject of the invention is the applications of the product:
as glazing for transport vehicles (automobile, train or bus side windows, aircraft or automobile windshields) or for buildings;
as a glass-ceramic hob or oven door;
as a component of street furniture, especially as a component of a bus shelter;
as a furniture component, especially as a mirror, a storage shelf, a shelf for a domestic electric appliance such as a refrigerator, a shower cubicle component, a partition, tables, doors, a balustrade, etc.; and
as a screen, especially a television or computer screen, touch screen or plasma screen.

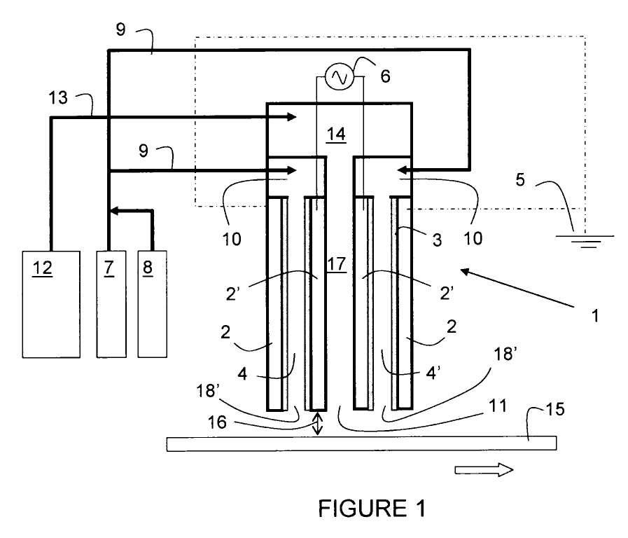

FIG. 1 illustrates one preferred, although not limiting, embodiment of the invention in which an inorganic silica sublayer and the hydrophobic layer are both deposited by bringing into contact, on a glass substrate, the mixture of a precursor of said layers and of a gas previously excited in a plasma generated at atmospheric pressure.

According to the invention, use is preferably made of a plasma known as “non-equilibrium” plasma or cold plasma, that is to say that the temperature of the gases is considerably below the electron temperature within the plasma. Generally, the temperature of the gases is below 300° C. The implementation of the embodiment illustrated by FIG. 1 incorporates, in particular, the use of a device, of known technology, generating a remote atmospheric plasma in nitrogen, often referred to in the field as “dielectric barrier discharge” or else DBD. Without departing from the scope of the invention, the substrate may be flat or have previously undergone a shaping operation such as a bending operation before the deposition of the hydrophobic coating.

More specifically, use is made, in this example of the implementation of the invention, of an indirect plasma machine having 3 slots, of which a synoptic representation 1 is given by FIG. 1. The fluoro precursor of the hydrophobic layer is projected toward the substrate by means of the central slot 11, the two outer slots 18, 18′ allowing the projection of two curtains of gases excited by plasma discharges generated upstream. The precursor is therefore, according to the invention, mixed in post-discharge, that is to say brought into contact with the excited gases (plasma) downstream of the discharge zones.

The means that make it possible to generate the plasma are made up of two pairs of outer 2 and inner 2′ parallel planar electrodes. Each of the planar electrodes 2, 2′ is covered with a dielectric 3. The space present between two electrodes 2 and 2′ that are opposite each other delimit volumes or zones respectively numbered 4 and 4′ in FIG. 1, in which a substantially atmospheric pressure plasma is generated. The dielectric is, for example, based on alumina, typically deposited by plasma spray technologies, but any other type of dielectric or deposition process may be used. The inter-electrode distance is generally between 0.5 and 10 mm, preferably between 1 and 3 mm, especially when the plasma gas is mainly composed of nitrogen. The outer electrodes 2 are connected to a ground 5 and the inner electrodes 2′ are connected to an A.C. power supply 6, the reverse also being possible. In a known manner, a plasma is generated in a gas introduced into zones 4 and 4′ by switching on the electrodes at a frequency and an amplitude chosen according to the techniques of the art. The plasma slots are supplied with plasma gas from a reservoir 7 and optionally with additives stored in a container 8 by means of gas lines 9. The gases are homogenized and distributed via injection chambers 10, that are kept in fluid contact with zones 4 and 4′. The fluoro precursor, stored in a reservoir 12, is introduced via a gas line 13 into the injection chamber 14. Without departing from the scope of the invention, the precursor may be either gaseous, or liquid or solid. This is carried out by conventional means, especially by bubbling if the precursor is liquid, or by vaporization in the case of a liquid or solid precursor dissolved in a solvent. Advantageously, the compound is mixed and homogenized in the chamber 14 with a dilution gas (not shown), the composition of which is, for example, close or identical to that of the plasma gas used to supply the chambers 10. The mixture of the gases (fluoro compound and dilution gas) spreads through the volume 17 generated between the two pairs of electrodes 2, 2′ and is evacuated by the injection slot 11, located between the two outlet slots 18, 18′ of the discharge plasma generated respectively in zones 4 and 4′.

All of the gases (dilute organic fluoro compound and plasma gas) are blown as a mixture toward the glass substrate 15 which travels under the device, thus allowing the activated organic fluoro compound to come into contact with it and the layer to be deposited on said substrate. The distance 16 between the device and the substrate may be between 1 mm and 5 cm, preferably between 2 mm and 1 cm.

The length of the slots 11, 18, 18′ is advantageously equal to the width of the part of the substrate onto which the coating should be deposited. Alternatively, it is also possible, according to the invention, to produce a deposition tool of reduced size which is moved, for example, by means of an XY table or a 3-axes (X, Y and Z) robot above the substrate. This is particularly indicated for the treatment of curved substrates.

The present invention is not limited to the preceding embodiment and other alternative embodiments that derive from the present description are of course within the scope of the present invention, such as those described in Application US 2004/247886.

The following examples serve to illustrate the invention without however limiting the scope thereof, under any of the aspects described.

### EXAMPLE 1

### According to the Prior Art

According to this example, a first sample E1 was prepared according to the teachings of Patent EP 799 873.

Priming of the glass: The priming solution was obtained from a mixture of 0.3 wt % Si(OC₂H₅)₄ in a solution of 90 wt % of isopropanol and 10 wt % of an aqueous 0.3N HCl solution, during the first deposition step.

At the same time, a 3% solution of perfluorodecyltriethoxysilane CF₃ (CF₂) 7 (CH₂)₂Si(OC₂H₅)₃ in the isopropanol (90%)/aqueous 0.3 N hydrochloric acid solution (10%) mixture was prepared. The two solutions were stirred for 15 minutes.

According to a first deposition step, the priming solution was then deposited by wiping over the air side of a soda-lime glass substrate sold by Saint-Gobain Glass France under the trade mark Planilux® that had previously been polished using a cerium oxide solution then profusely rinsed with demineralized water. The thickness of this layer thus obtained was between 5 and 10 nm.

Deposition of the hydrophobic layer: As soon as the deposition of the sublayer had been carried out, the solution of perfluorodecyltriethoxysilane was in turn deposited by the same wiping technique. In this example, the deposition of the various layers was carried out by the well-known technique of wiping, in which the material or its precursor was deposited using a soaked cloth.

After a waiting period of 15 minutes at ambient temperature, the excess fluorosilane was removed by cleaning with a cloth soaked in isopropanol.

### EXAMPLE 2

### According to the Prior Art

The step of applying the hydrophobic layer from the previous example was reproduced for the preparation of a second sample E2, but the Planilux® glass substrate was this time covered with a 100 nm layer of SiO₂ obtained by pyrolysis, in accordance with the teachings from example 3 of EP 545 201 A2.

According to techniques identical to those from example 1, a 3% solution of CF₃(CF₂)₇(CH₂)₂Si(OC₂H₅)₃ in a mixture of 90% ethanol and 10% water, acidified with 0.3 N HCl was applied by the wiping technique to the substrate covered with the sublayer.

### EXAMPLE 3

### According to the Prior Art

A third sample E3 was prepared in accordance with the teachings of Application WO 2005/084943. Sample E3 was obtained by wiping a fluorosilane solution over a 50 nm thick SiO₂ sublayer according to the method described in example 2 of WO 2005/084943. This sublayer had first been deposited on the Planilux® glass substrate in a low-pressure PECVD reactor then texturized using an atmospheric pressure plasma, in accordance with the operating procedure described according to example 2 of this disclosure.

### EXAMPLE 4

### Comparative

A fourth sample was prepared by direct deposition of a hydrophobic layer starting from the compound CF₃(CF₂)₇(CH₂)₂Si(OC₂H₅)₃ using the device illustrated by FIG. 1 and passing the Planilux® glass substrate under said device. The width of the slots in the direction perpendicular to the direction of travel of the glass was 120 mm.

The deposition was carried out according to the following conditions:

### 1) Gas Conditions:

implementation of the precursor by bubbling nitrogen in a bubbler:
bubbling flow rate: N₂=1 l/min, temperature of the bubbler=80° C.
plasma slots: total N₂ flow rate in each slot=50 l/min.
precursor slot: total flow rate of the N₂ and fluorosilane mixture in the slot=50 l/min.

### 2) Power Supply Condition:

power: 1 kW, frequency: 18 kHz.

The power supply was an electrical power supply with a voltage delivering a pulsed signal with a pulse duration of 5 μs and a repetition frequency of 18 kHz.

The glass was moved under the nozzle, with a rate of travel of 0.5 m/min.

### EXAMPLE 5

### According to the Invention

A fifth sample was prepared by deposition of a hydrophobic layer starting from the compound CF₃(CF₂) 7 (CH₂)₂Si(OC₂H₅)₃ using the device illustrated by FIG. 1 and passing the Planilux® glass substrate under said device. Unlike example 4 and in accordance with the invention, a silica sublayer was this time previously deposited using an identical device before the deposition of the hydrophobic layer. The experimental conditions for the successive depositions of the sublayer and of the hydrophobic layer were the following:

### 1st Step: Deposition of a Silica Sublayer

The deposition was carried out in this example starting from tetraethoxysilane (TEOS) and oxygen on a soda-lime glass (SGG-Planilux®) with a plasma source of the type of that described with respect to FIG. 1, having a dimension of 12 cm in width.

Of course, according to the invention other precursors may be used, preferably chosen from organometallics or halides, as a mixture with an oxidizing or reducing gas.

### 1) Gas Conditions:

plasma slots: the gas was a mixture of N₂ and 1 vol % of O₂, the total flow rate in each slot being 50 l/min,
precursor slot: the gas was a mixture of N₂ and 0.2 vol % of TEOS (conveyed by bubbling), total flow rate in the slot=50 l/min.

### 2) Power Supply Conditions:

power: 2 kW, frequency 30 kHz.

The glass was moved under the nozzle, with a rate of travel of 0.5 m/min. The power supply was identical to that from example 4.

The layer obtained had a thickness of 50 nm, a density of 2.1 g/cm³, few carbon-based residues as shown by measurement with an electronic microprobe device, very good adhesion to the glass (no delamination after 600 cycles of a “Taber” abrasion test, carried out according to the ASTM D1044-78 standard (CS-10F wheels, load of 500 g)).

### 2nd Step: Deposition of the Hydrophobic Layer

The pretreated glass (with the silica sublayer) traveled under the same equipment as in example 4. The deposition conditions were identical to those from example 4. The glass was moved under the nozzle, with a rate of travel of 0.5 m/min.

The power supply was identical to that from example 4.

### EXAMPLE 6

### According to the Invention

In this example, the exact same compounds, conditions and steps described in example 5 were repeated apart from the rate of travel of the glass during the deposition of the silica sublayer: the glass was moved this time at 0.9 m/min. The thickness of the sublayer thus obtained was 28 nm.

### EXAMPLE 7

### According to the Invention

In this example, the exact same compounds, conditions and steps described in example 5 were repeated apart from the rate of travel of the glass during the deposition of the silica sublayer: the glass was moved this time at 2.5 m/min. The thickness of the sublayer thus obtained was 10 nm.

The seven samples E1 to E7, prepared according to examples 1 to 7, were evaluated according to the following criteria:

1) Measurement of the initial performances: the measurement of the initial contact angle of a drop of water and of hexadecane, provides a reference indication of the hydrophobic or oleophobic character of the grafted substrate, the measurements of hysteresis (difference between the advancing contact angle and the receding contact angle) and of the volume necessary for the detachment of one drop, the substrate being inclined by 45°, provide an indication of the performance of the glass when the vehicle is moving (the speed necessary to detach the drops being proportionally low when the hysteresis and the detachment volume are low).

2) The frictional resistance, obtained by measuring the residual contact angle of the water on the sample after the grafted hydrophobic/oleophobic coating had undergone a Toyota® friction test. The test is carried out according to the TSR7503G standard, with a load of 0.3 kg/cm² over a surface area of 4 cm², a translational speed of 40 cycles/minute and using a device manufactured by Daiei Kagaku Seiki. A sample is judged to pass the test for side window applications if the contact angle remains above 800 after 1500 cycles (TSR7102G-5 standard). For windshield applications, the contact angle must remain above 800 after 2500 cycles (TSR7102G-3 standard). The frictional test was continued up to 10 000 cycles, provided that the contact angle remains above 80°.

3) The resistance to UV-A radiation is measured by a UV-humid test representing the climate of a humid region (for example, Florida), according to the PV 3930 standard. The test was carried out on an Atlas WOM Ci 65 machine with an exposure of 0.6 W/m² for a wavelength of 340 nm, with a relative humidity of 60 to 80% and a temperature of 35 to 45° C. The exposure was in all cases 1000 hours.

4) The resistance to salt corrosion, measured by the Neutral Salt Spray (NSS) test as described according to NF ISO 9227 standard. The test consists of spraying fine droplets of saline water (50 g/l NaCl solution with a pH of 7), at a temperature of 35° C. over the sample. The test was carried out for 21 days, provided that the contact angle of the drop was above 60°.

The results obtained for the samples prepared in accordance with examples 1 to 7 are reported in table 1:

TABLE 1

| | | | Hydrophobicity | | | | | | | |
|---|---|---|---|---|---|---|---|---|---|---|
| | Initial contact | | properties | | Frictional resistance | | | UV resistance | | |
| | angle | | | Detachment | | | Angle after | Angle after | NSS test | |
| | | Hexa- | | volume in | Angle after | Angle after | Toyota test | Florida UV | Time | Contact |
| | Water | decane | Hysteresis | μl (45° | Toyota test | Toyota test | 10 000 | test | (contact | angle after |
| Sample | (°) | (°) | (in °) | incline) | 1500 cycles | 2500 cycles | cycles | (1000 hours) | angle < 60°) | 21 days |
| E1 | 105 | 70 | 22 | 18 | 91° | 63° | <<80° | 90 | 3 days | — |
| E2 | 106° | 69° | 25° | 20° | 93° | 65° | <<80° | 95 | >>21 days | 97 |
| E3 | 115 | 70 | 40 | 27 | 104° | 99° | 93° | 96 | >>21 days | 100 |
| E4 | 112 | 65 | 13 | 16 | 112° | 109° | 110° | 82 | 10 days | — |
| E5 | 114 | 62 | 12 | 19 | 110° | 108° | 109° | 98 | >>21 days | 111 |
| E6 | 114 | 63 | 13 | 18 | 109° | 110° | 110° | 97 | >>21 days | 112 |
| E7 | 113 | 64 | 13 | 17 | 110° | 109° | 107° | 96 | >>21 days | 105 |

The comparison of the data reported in table 1 shows that the examples E5 to E7, in accordance with the invention and that are characterized by the combination of a sublayer and a hydrophobic/oleophobic layer deposited by means of an atmospheric plasma, result in initial hydrophobicity/oleophobicity properties that are generally better or at least substantially equal to those of the prior art. The samples according to the invention have, besides these very good initial performances, a very good climatic resistance (NSS and UV-humid tests), and mechanical strength (Toyota test). The combination of these three excellent properties is unknown to date.

More particularly, sample E1 has initial and frictional resistance properties that are acceptable with respect to the current automobile specifications for side window applications but an insufficient chemical resistance.

Sample E2 has initial hydrophobic and mechanical strength properties similar to E1 with an improved chemical resistance.

Sample E3, although it has remarkable mechanical strength properties, much greater than examples E1 and E2 and compatible with use as an automobile windshield, with good climatic durability properties, has the drawback of a high hysteresis and a detachment volume of the drop greater than the other samples, that is expressed by a drop in initial functionality. Furthermore, the process used to produce the rough sublayer is a complex (multi-step) and expensive (deposition of the sublayer and etching thereof under vacuum) process.

Sample E4 has extremely high initial and mechanical strength properties (at least equal to E3) but a chemical resistance in the NSS and TV-humid tests that is very inadequate.

Only samples E5 to E7 produced according to the invention make it possible to combine very good initial performances, a remarkable mechanical strength, and a very good climatic durability, with a deposition process that is simplified and/or of lower cost compared to the alternative techniques (depositions via a liquid route or under vacuum).

1. A method for synthesizing a hydrophobic coating on a glass, ceramic or glass-ceramic substrate, comprising
first depositing a sublayer having a thickness of between 1 and 100 nm on said substrate; and
contacting said substrate with a gaseous mixture comprising an excited gas originating from a device generating a substantially atmospheric pressure plasma and at least one fluoro compound.

2. The method as claimed in claim 1, in which the sublayer comprises at least one inorganic compound selected from the group consisting of a metal oxide, a metal nitride, a metal carbide, a metal oxycarbide, and a metal oxynitride.

3. The method as claimed in claim 2, in which the sublayer comprises an inorganic compound selected from the group consisting of SiO₂, Al₂O₃, Ga₂O₃, SnO₂, TiO₂, Ta₂O₅, Cr₂O₃, ZrO₂, Nb₂O₅, In₂O₃, Fe₂O₃, CoO₃, V₂O₅, Y₂O₃, TiN, and SiOₓ, wherein
for SiOₓ, x less than 2, and for SiOₚC_{q} and SiOₚN_{q} p is between 1 and 2 and q is between 0 and 1, alone or in combination.

4. The method as claimed in claim 2, in which the inorganic compound is doped so as to make it electron and/or ion conducting or so as to improve the hydrolytic resistance thereof or else so as to modify the optical properties thereof.

5. The method as claimed in claim 1, in which the sublayer is deposited by means of a device generating a substantially atmospheric pressure plasma.

6. The method as claimed in claim 1, in which the sublayer is deposited by magnetron sputtering, by thermal CVD or plasma-enhanced CVD at low pressure or by a sol-gel route.

7. The method as claimed in claim 1, in which the fluoro compound is a fluorinated organometallic compound of formula: 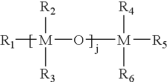
in which
M is an element selected from the group consisting of Si, Ti, Al, Ge, Zr and Sn, and
R₁ to R₆ represent hydrogen or groups comprising at least one carbon atom, at least one of the groups R₁ to R₆ comprising fluorine.

8. The method as claimed in claim 1, in which the fluoro compound is a fluorosilane of formula:
R-A-Z-[SiX₂O]ₙ—Si(X₃₋ₚ)(R′ₚ)
in which
R is a fluorocarbon-based chain,
A is a fluorocarbon-based chain that may be interrupted by ether —O— or thioether —S— groups,
Z is a bridging group between the fluoro chain and the silane
X is a halogen or an alkoxy group
R′ is an alkyl group or a hydrogen atom,
n is between 0 and 5 and
p is between 0 and 3.

9. The method as claimed in claim 8, in which the fluoro compound is a perfluoroalkylsilane of formula (II):
F₃C—(CF₂)ₘ—(CH₂)ₙ—Si(X₃₋ₚ)(R′ₚ) (II)
in which:
m=0 to 15;
n=1 to 5;
p=0, 1 or 2;
R′ is an alkyl group or a hydrogen atom; and
X is a hydrolyzable group or an alkoxy group.

10. The method as claimed in claim 1, in which the fluoro compound is selected from the group consisting of:
a fluorocarbon-based precursor comprising only C, H and F,
a saturated fluoro compound represented by formula CₙFₙ₊₂,
an unsaturated fluoro compound represented by formula CₙF₂ₙ, and
a fluoroether represented by formula CₙF₂ₙO,
wherein n is an integer that varies from 1 to 20.

11. The method as claimed in claim 1, in which the gaseous mixture comprises
at least one precursor and
at least one fluoro compound that is
i) a fluorinated organometallic compound of formula: 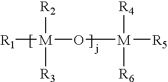
in which
M is an element selected from the group consisting of Si, Ti, Al, Ge, Zr and Sn, and
R₁ to R₆ represent hydrogen or groups comprising at least one carbon atom, at least one of the groups R₁ to R₆ comprising fluorine;
ii) a fluorosilane of formula:
R-A-Z-[SiX₂O]ₙ—Si(X₃₋ₚ)(R′ₚ)
in which
R is a fluorocarbon-based chain,
A is a fluorocarbon-based chain that may be interrupted by ether —O— or thioether —S— groups,
Z is a bridging group between the fluoro chain and the silane,
X is a halogen or an alkoxy group
R′ is an alkyl group or a hydrogen atom,
n is between 0 and 5, and
p is between 0 and 3;
iii) a perfluoroalkylsilane of formula (II):
F₃C—(CF₂)ₘ—(CH₂)ₙ—Si(X₃₋ₚ)(R′ₚ) (II)
in which:
m=0 to 15;
n=1 to 5;
p=0, 1 or 2;
R′ is an alkyl group or a hydrogen atom; and
X is a hydrolyzable group or an alkoxy group; and
iv) a fluoro compound that is selected from the group consisting of:
a fluorocarbon-based precursor comprising only C, H and F,
a saturated fluoro compound represented by formula CₙF₂ₙ₊₂,
an unsaturated fluoro compound represented by formula CₙF₂ₙ, and
a fluoroether represented by formula CₙF₂ₙO,
wherein n is an integer that varies from 1 to 20.

12. A product of which the outer surface, comprises a glass, ceramic or glass-ceramic material, is at least partly equipped with a hydrophobic/oleophobic coating,
said product obtained by the method as claimed in claim 1.

13. The product as claimed in claim 12, which is a monolithic, laminated or multiple glazing.

14. The product as claimed in claim 12, in the form of a glazing for a transport vehicle or for buildings.

15. The product as claimed in claim 12, in the form of a glass-ceramic hob or oven door.

16. The product as claimed in claim 12, in the form of a street furniture, a furniture component, a storage shelf, a shelf for a domestic electric appliance, a shower cubicle component, a partition, a table, a balustrade, or as a screen.

17. The method as claimed in claim 1, wherein said substrate is a glass substrate.

18. The method as claimed in claim 8, wherein X is Cl or I.

19. The method as claimed in claim 9, wherein
m=5 to 9;
n=2;
p=1 or 2.

20. The method as claimed in claim 9, wherein
p=0.

21. The method as claimed in claim 11, wherein X of said fluorosilane is Cl or I.

22. The method as claimed in claim 11, wherein
m=5 to 9;
n=2;
p=1 or 2
of said perfluoroalkylsilane.

23. The method as claimed in claim 11, wherein
p=0
of said perfluoroalkylsilane.

24. The method as claimed in claim 11, wherein said precursor is at least one selected from the group consisting of an organometallic, an organosilica and a halide of Si, Al, Ti, Sn, or Zr.

25. The method as claimed in claim 9, wherein said hydrolysable group is chloride.

26. The product as claimed in claim 13, in the form of a glazing for a transport vehicle or for buildings.

27. The product as claimed in claim 13, in the form of a glass-ceramic hob or oven door.

28. The product as claimed in claim 13, in the form of a street furniture, a furniture component, a storage shelf, a shelf for a domestic electric appliance, a shower cubicle component, a partition, a table, a balustrade, or as a screen.

29. The product as claimed in claim 16, in the form of a bus shelter, a mirror, a refrigerator, a television screen, a touch screen, or a plasma screen.

30. The product as claimed in claim 28, in the form of a bus shelter, a mirror, a refrigerator, a television screen, a touch screen, or a plasma screen.
